(19) United States
(12) Patent Application Publication
(10) Pub. No.: US 2026/0086148 A1
(43) Pub. Date: Mar. 26, 2026

(54) TEST APPARATUS, TEST METHOD, AND PROGRAM

(71) Applicant: ADVANTEST CORPORATION, Tokyo (JP)

(72) Inventors: Tokunori AKITA, Saitama (JP); Takeshi KAWAKAMI, Gunma (JP); Masaki FUJIWARA, Gunma (JP)

(21) Appl. No.: 19/409,791

(22) Filed: Dec. 5, 2025

Related U.S. Application Data
(63) Continuation of application No. PCT/JP2023/034643, filed on Sep. 25, 2023.

(51) Int. Cl. G01R 31/3181; G01R 31/317

(52) U.S. Cl. CPC G01R 31/31813; G01R 31/31723; G01R 31/31727

(57) ABSTRACT

Provided is a test apparatus including: a pattern generation unit which generates a protocol pattern for testing a device under test, the protocol pattern having a plurality of cycles, each cycle consisting of a predetermined specified number of at least one signal pattern; and a sequence control unit which controls the pattern generation unit in accordance with a first instruction having a plurality of steps and a second instruction having a plurality of steps, wherein the pattern generation unit generates the protocol pattern such that at least one cycle of the plurality of cycles includes a signal pattern corresponding to at least one step included in the first instruction and a signal pattern corresponding to at least one step included in the second instruction.

The contents of the following patent application(s) are incorporated herein by reference:

NO. PCT/JP2023/034643 filed in WO on September 25, 2023.

### BACKGROUND

### 1. TECHNICAL FIELD

The present invention relates to a test apparatus, a test method, and a program.

### 2. RELATED ART

Patent Document 1 describes "a test apparatus and a test method for testing a memory-under-test".

### RELATED ART DOCUMENTS

### PATENT DOCUMENTS

Patent Document 1: Japanese Patent Application Publication No. 2007-200371

Patent Document 2: Japanese Patent Application Publication No. 2010-165422

Patent Document 3: Japanese Patent Application Publication No. 2009-93227

Patent Document 4: Japanese Patent Application Publication No. 2012-103016

### BRIEF DESCRIPTION OF THE DRAWINGS

FIG. 1 shows one example of a configuration of a test apparatus 100 together with a device under test 10.

FIG. 2 shows one example of a configuration of an ALPG 20.

FIG. 3A shows one example of generation of a protocol pattern PAT.

FIG. 3B shows generation of a protocol pattern PAT according to a comparative example.

FIG. 4A shows a modified example of generation of a protocol pattern PAT.

FIG. 4B shows generation of a protocol pattern PAT according to a comparative example.

FIG. 5 shows one example of a flowchart of generation of a protocol pattern PAT.

FIG. 6 shows one example of a configuration of a pattern generator 240 together with a sequence control unit 22, a memory unit 26, and a first multiplexer 258.

FIG. 7 shows a modified example of generation of a protocol pattern PAT.

FIG. 8 shows one example of a computer 1000 in which a plurality of aspects of the present invention may be embodied in whole or in part.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to solutions of the invention.

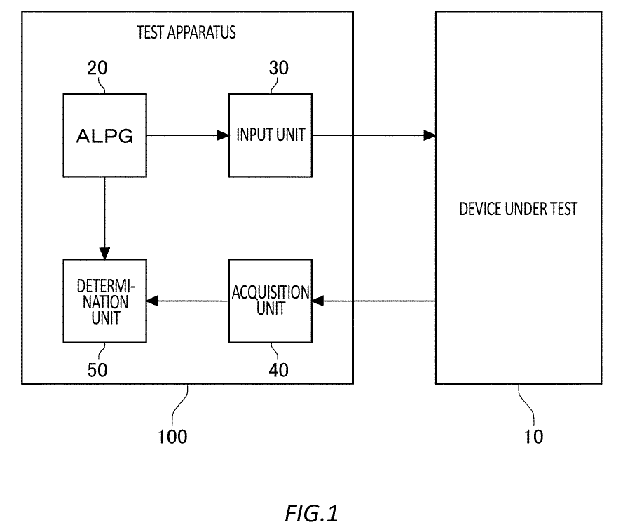

FIG. 1 shows one example of a configuration of a test apparatus 100 together with a device under test 10. The test apparatus 100 includes an ALPG 20, an input unit 30, an acquisition unit 40, and a determination unit 50, and tests the device under test 10 such as an analog circuit, a digital circuit, a memory, or a system-on-chip (SOC). The test apparatus 100 inputs, to the device under test 10, a test signal which is based on a protocol pattern PAT for testing the device under test 10, and determines a quality of the device under test 10 based on a response signal outputted from the device under test 10 in response to the test signal.

The ALPG 20 produces the protocol pattern PAT for testing the device under test 10. In addition, the ALPG 20 produces an expected value pattern expected as the response signal to be outputted from the device under test 10.

The input unit 30 generates the test signal which is based on the protocol pattern PAT produced by the ALPG 20, and inputs the test signal to the device under test 10. The acquisition unit 40 acquires the response signal outputted from the device under test 10.

The determination unit 50 compares the response signal of the device under test 10 acquired by the acquisition unit 40 with the expected value pattern produced by the ALPG 20. The determination unit 50 determines the quality of the device under test 10 based on a result of comparing the response signal with the expected value pattern.

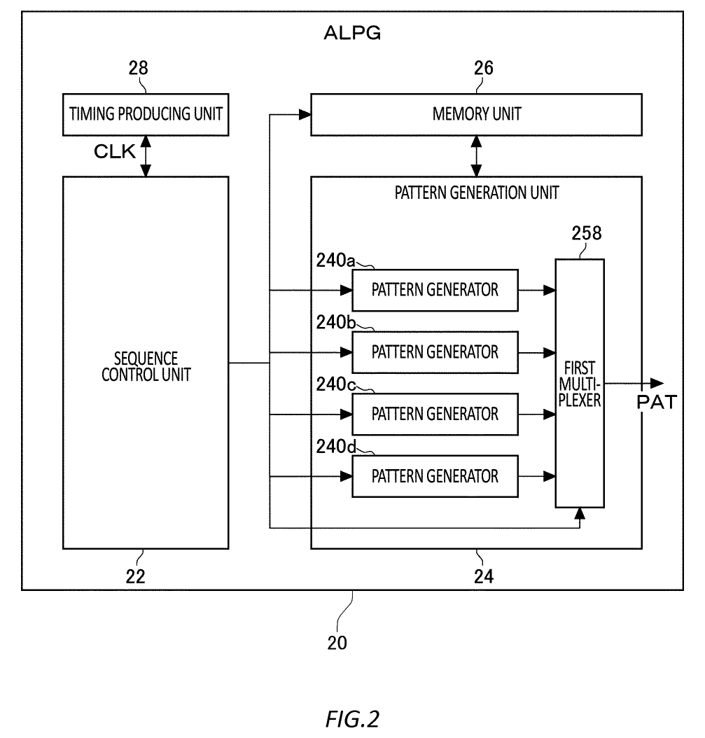

FIG. 2 shows one example of a configuration of the ALPG 20. The ALPG 20 includes a sequence control unit 22 and a pattern generation unit 24. The ALPG 20 may include a memory unit 26 and a timing producing unit 28.

The pattern generation unit 24 generates a protocol pattern PAT for testing the device under test 10. The protocol pattern PAT has a plurality of cycles. Each cycle consists of a predetermined specified number of at least one signal pattern. The protocol pattern PAT will be described later in detail.

The sequence control unit 22 controls the pattern generation unit 24 in accordance with a plurality of inputted instructions. Each of the plurality of instructions may include a plurality of steps. The sequence control unit 22 controls the pattern generation unit 24 in accordance with a first instruction having a plurality of steps and a second instruction having a plurality of steps. The first instruction and the second instruction may be two consecutive instructions of the plurality of instructions inputted to the sequence control unit 22. The sequence control unit 22 may control the pattern generation unit 24 to generate signal patterns corresponding to respective steps of the first instruction and signal patterns corresponding to respective steps of the second instruction. The pattern generation unit 24 may generate the protocol pattern PAT as one continuous pattern including the signal patterns corresponding to the respective steps of the first instruction and the signal patterns corresponding to the respective steps of the second instruction. The first instruction and the second instruction will be described later in detail.

The memory unit 26 may store the signal patterns corresponding to the respective steps of the first instruction and the second instruction. The memory unit 26 may respectively store, at different addresses, the signal patterns corresponding to the respective steps of the first instruction and the second instruction. For example, the memory unit 26 stores, at an address 0, the signal patterns corresponding to the respective steps of the first instruction, and stores, at an address 1, the signal patterns corresponding to the respective steps of the second instruction.

The pattern generation unit 24 may generate the signal patterns corresponding to the respective steps of the first instruction and the second instruction by accessing the memory unit 26. The sequence control unit 22 may control the pattern generation unit 24 to access the memory unit 26 in order to cause the pattern generation unit 24 to generate the signal patterns corresponding to the respective steps of the first instruction and the second instruction.

The timing producing unit 28 may produce a clock signal CLK. The sequence control unit 22 may control the pattern generation unit 24 in synchronization with the clock signal CLK produced by the timing producing unit 28. A period of each of the plurality of cycles included in the protocol pattern PAT may be the same as a period of the clock signal CLK. That is, one period of the clock signal CLK may correspond to one cycle of the protocol pattern PAT.

The pattern generation unit 24 may have a plurality of pattern generators 240 and a first multiplexer 258. The pattern generation unit 24 in the present example has four pattern generators 240. A number of at least one pattern generator 240 included in the pattern generation unit 24 is not limited thereto. The pattern generation unit 24 may have three or fewer pattern generators 240, or may have five or more pattern generators 240. As one example, the number of at least one pattern generator 240 included in the pattern generation unit 24 is a power of two.

Each of the plurality of pattern generators 240 may generate a signal pattern corresponding to at least one step of the first instruction or the second instruction. For example, when the first instruction has four steps, a pattern generator 240a may generate a signal pattern corresponding to a first step, a pattern generator 240b may generate a signal pattern corresponding to a second step, a pattern generator 240c may generate a signal pattern corresponding to a third step, and a pattern generator 240d may generate a signal pattern corresponding to a fourth step.

The first multiplexer 258 may output, as one continuous signal pattern, a composition of signal patterns respectively outputted from the plurality of pattern generators 240. The first multiplexer 258 may output the combined signal patterns as the protocol pattern PAT. For example, when the first instruction has four steps and the pattern generators 240a to 240d respectively generate the signal patterns corresponding to the first to fourth steps, the first multiplexer 258 may combine the signal patterns corresponding to the first to fourth steps and output, as the protocol pattern PAT, the signal patterns corresponding to the respective steps of the first instruction.

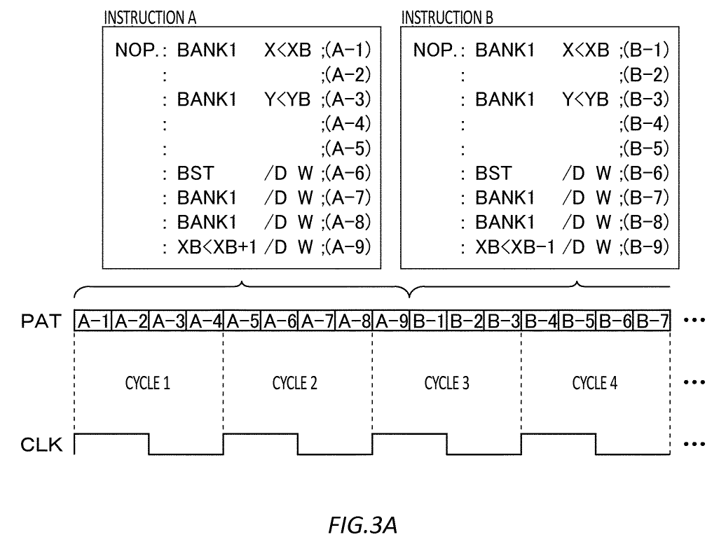

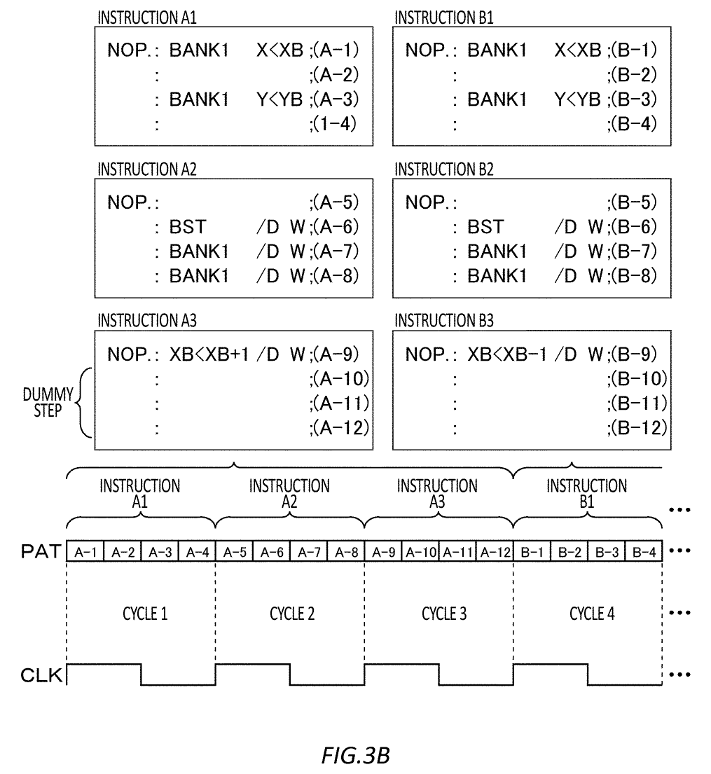

FIG. 3A shows one example of generation of a protocol pattern PAT. The protocol pattern PAT in the present example includes signal patterns corresponding to respective steps of Instruction A and Instruction B. Instruction A and Instruction B are respectively examples of a first instruction and a second instruction. Instruction A has nine steps (A-1) to (A-9). Instruction B has nine steps (B-1) to (B-9).

The protocol pattern PAT in the present example has at least four cycles, and each cycle includes four signal patterns. That is, a specified number of at least one signal pattern in the present example is four. The specified number of at least one signal pattern may be equal to a number of the plurality of pattern generators 240. Each of the plurality of pattern generators 240 may generate one signal pattern per cycle, whereby the specified number of at least one signal pattern in each cycle may be equal to the number of the plurality of pattern generators 240. As with the number of the plurality of pattern generators 240, the number may be three or fewer, or may be five or more. As one example, the specified number of at least one signal pattern is a power of two.

A number of a plurality of steps included in the first instruction may be greater than the specified number of at least one signal pattern. A number of at least one step included in Instruction A in the present example is nine, which is greater than the specified number of at least one signal pattern (four in the present example). A number of a plurality of steps included in the second instruction may be the same as the specified number of at least one signal pattern, or may be greater than the specified number of at least one signal pattern. A number of at least one step included in Instruction B in the present example is nine, which is greater than the specified number of at least one signal pattern.

The pattern generation unit 24 generates the protocol pattern PAT such that at least one cycle of a plurality of cycles includes a signal pattern corresponding to at least one step included in the first instruction and a signal pattern corresponding to at least one step included in the second instruction. The pattern generation unit 24 in the present example generates the protocol pattern PAT such that Cycle 3 includes a signal pattern corresponding to the step (A-9) included in Instruction A and signal patterns corresponding to the steps (B-1) to (B-3) included in Instruction B.

Thus, the pattern generation unit 24 in the present example generates the protocol pattern PAT such that at least one cycle includes signal patterns corresponding to at least one respective step of a plurality of instructions. This allows efficient processing of an instruction having a number of steps greater than the specified number of at least one signal pattern.

It should be noted that, although cycles 1 to 4 are illustrated in the present figure, the protocol pattern PAT may have cycles after Cycle 4. For example, the protocol pattern PAT in the present example has, at least, Cycle 5 including signal patterns corresponding to the steps (B-8) and (B-9) of Instruction B. In Cycle 5, after the signal patterns corresponding to the steps (B-8) and (B-9) of Instruction B, a signal pattern corresponding to a step of another instruction may further be included.

FIG. 3B shows generation of a protocol pattern PAT according to a comparative example. In the protocol pattern PAT according to the comparative example, a number of at least one step included in each instruction must coincide with a specified number of at least one signal pattern.

In the comparative example, Instruction A having nine steps is rewritten into Instructions A1 to A3 each having four steps, such that the number of at least one step included in each instruction coincides with the specified number of at least one signal pattern. Similarly, Instruction B having nine steps is rewritten into instructions B1 to B3 each having four steps. Further, dummy steps such as steps (A-10) to (A-12) and steps (B-10) to (B-12) are added such that the number of at least one step included in each instruction coincides with the specified number of at least one signal pattern.

The pattern generation unit 24 according to an example generates the protocol pattern PAT such that at least one cycle includes signal patterns corresponding to at least one respective step of a plurality of instructions, thereby allowing efficient processing of an instruction having a number of steps greater than the specified number of at least one signal pattern without rewriting the instruction and/or adding dummy steps to the instruction.

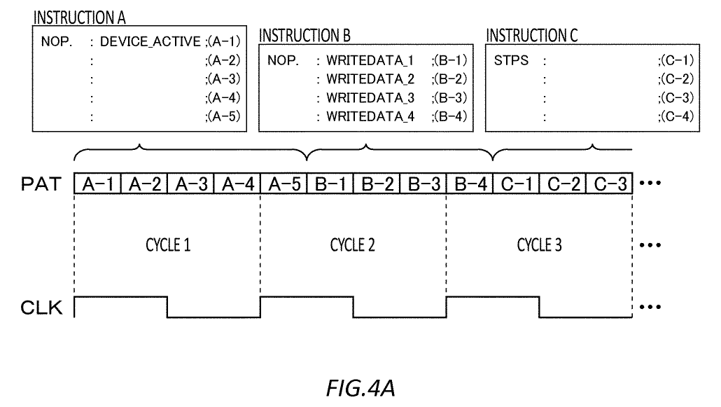

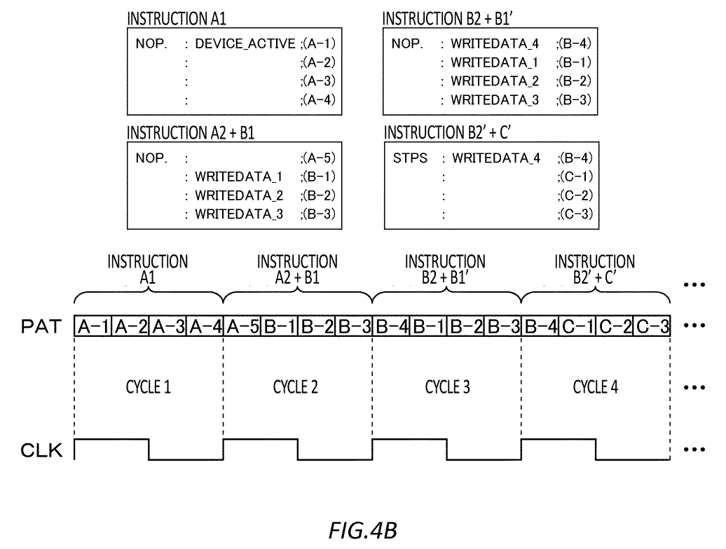

FIG. 4A shows a modified example of generation of a protocol pattern PAT. The protocol pattern PAT in the present example includes signal patterns corresponding to respective steps of Instruction A, Instruction B, and Instruction C. Instruction A and Instruction B are examples of a first instruction and a second instruction, and Instruction B and Instruction C are other examples of the first instruction and the second instruction. Instruction A has five steps (A-1) to (A-5), a number of which is greater than a specified number of at least one signal pattern (four in the present example). Instruction B has four steps (B-1) to (B-4), a number of which is equal to the specified number of at least one signal pattern. Instruction C has four steps (C-1) to (C-4), which is equal to the specified number of at least one signal pattern.

The pattern generation unit 24 in the present example generates the protocol pattern PAT such that Cycle 2 includes a signal pattern corresponding to the step (A-5) included in Instruction A and signal patterns corresponding to the steps (B-1) to (B-3) included in Instruction B. In this case, Instruction A corresponds to the first instruction, and Instruction B corresponds to the second instruction. In addition, the pattern generation unit 24 in the present example generates the protocol pattern PAT such that Cycle 3 includes a signal pattern corresponding to the step (B-4) included in Instruction B and signal patterns corresponding to the steps (C-1) to (C-3) included in Instruction C. In this case, Instruction B corresponds to the first instruction, and Instruction C corresponds to the second instruction. Thus, the pattern generation unit 24 generates the protocol pattern PAT such that at least one cycle includes signal patterns corresponding to at least one respective step of a plurality of instructions, thereby allowing efficient processing of an instruction having a number of steps greater than the specified number of at least one signal pattern.

FIG. 4B shows generation of a protocol pattern PAT according to a comparative example. In the comparative example, Instruction A, Instruction B, and Instruction C are rewritten into Instruction A1, Instruction A2+B1, Instruction B2+B1’, and Instruction B2’+C’ such that a number of at least one step included in each instruction coincides with a specified number of at least one signal pattern. Thus, when the number of at least one step included in each instruction must coincide with the specified number of at least one signal pattern, even more complicated rewriting of the instruction may be required than in the comparative example shown in FIG. 3B.

The pattern generation unit 24 according to an example generates the protocol pattern PAT such that at least one cycle includes signal patterns corresponding to at least one respective step of a plurality of instructions, thereby allowing efficient processing of an instruction having a number of steps greater than the specified number of at least one signal pattern without complicated rewriting of the instruction.

When a number of the plurality of pattern generators 240 included in the pattern generation unit 24 is increased in order to accelerate the test apparatus 100, the specified number of at least one signal pattern is also increased accordingly. In this case, when the instruction having the number of steps greater than the specified number of at least one signal pattern is to be processed, a problem of the complicated rewriting of the instruction and/or a dummy step becomes even more serious. The pattern generation unit 24 in the present example is also effective when the specified number of at least one signal pattern is increased, because it can generate the protocol pattern PAT such that at least one cycle includes signal patterns corresponding to at least one respective step of the plurality of instructions, to efficiently process the instruction having the number of steps greater than the specified number of at least one signal pattern. This allows the number of the plurality of pattern generators 240 to be increased, thereby accelerating the test apparatus 100.

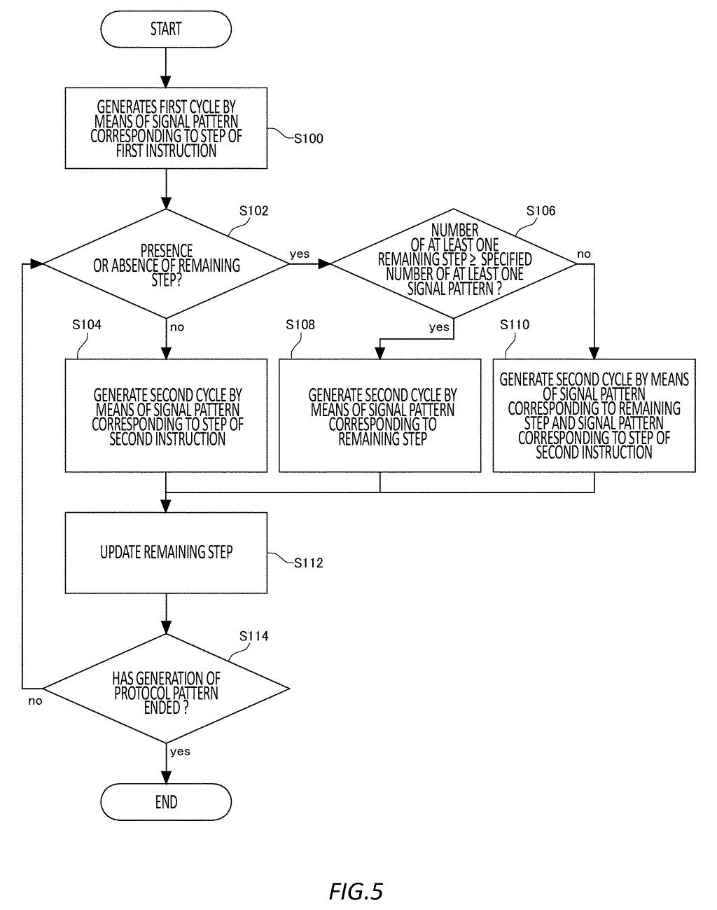

FIG. 5 shows one example of a flowchart of generation of a protocol pattern PAT. It should be noted, however, that a method of generating the protocol pattern PAT is not limited thereto. The protocol pattern PAT only needs to be generated such that at least one cycle includes signal patterns corresponding to at least one respective step of a plurality of instructions.

In Step S100, the pattern generation unit 24 generates a first cycle including a signal pattern corresponding to at least one step of a plurality of steps included in a first instruction. For example, in the example shown in FIG. 3A, the pattern generation unit 24 generates Cycle 1 including signal patterns corresponding to the steps (A-1) to (A-4) of the nine steps included in Instruction A. In this example, Cycle 1 corresponds to the first cycle. In addition, the pattern generation unit 24 generates Cycle 2 including signal patterns corresponding to the steps (A-5) to (A-8) of the nine steps included in Instruction A. In this example, Cycle 2 corresponds to the first cycle.

In Step S102, the sequence control unit 22 determines presence or absence of at least one remaining step, of the plurality of steps included in the first instruction, that has not been used for generation of the first cycle. For example, in the example shown in FIG. 3A, since the steps (A-5) to (A-9) of the nine steps included in Instruction A have not been used for generation of Cycle 1, the sequence control unit 22 determines that the at least one remaining step is present (yes). In this example, Cycle 1 corresponds to the first cycle. In addition, since the step (A-9) of the nine steps included in Instruction A has not been used for generation of Cycle 2, the sequence control unit 22 determines that the at least one remaining step is present (yes). In this example, Cycle 2 corresponds to the first cycle.

If it is determined in Step S102 that the at least one remaining step is absent (no), then in Step S104, the sequence control unit 22 controls the pattern generation unit 24 to generate a second cycle, which is a cycle following the first cycle, by means of a signal pattern corresponding to at least one step of a second instruction. That is, if the at least one remaining step is absent, it means that generation of signal patterns corresponding to respective steps of the first instruction has been completed, and therefore the pattern generation unit 24 may generate the second cycle by means of a signal pattern corresponding to at least one step of the second instruction.

If it is determined in Step S102 that the at least one remaining step is present (yes), then in Step S106, the sequence control unit 22 determines whether a number of the at least one remaining step is greater than or equal to a specified number of at least one signal pattern. For example, in the example shown in FIG. 3A, the sequence control unit 22 determines that a number of at least one remaining step, such as the steps (A-5) to (A-9), that has not been used for the generation of Cycle 1 is greater than or equal to the specified number of at least one signal pattern (four in the present example) (yes). In this example, Cycle 1 corresponds to the first cycle. In addition, the sequence control unit 22 determines that a number of at least one remaining step, such as (A-9), that has not been used for the generation of Cycle 2 is smaller than the specified number of at least one signal pattern (four in the present example) (no). In this example, Cycle 2 corresponds to the first cycle.

If it is determined in a step 106 that the number of the at least one remaining step is greater than or equal to the specified number of at least one signal pattern (yes), then in Step S108, the sequence control unit 22 controls the pattern generation unit 24 to generate the second cycle by means of a signal pattern corresponding to the at least one remaining step. For example, in the example shown in FIG. 3A, the sequence control unit 22 controls the pattern generation unit 24 to generate Cycle 2 by means of signal patterns corresponding to the steps (A-5) to (A-8) of the remaining steps (A-5) to (A-9) that have not been used for the generation of Cycle 1. In this example, Cycle 1 corresponds to the first cycle, and Cycle 2 corresponds to the second cycle.

If it is determined in Step S106 that the number of the at least one remaining step is smaller than the specified number of at least one signal pattern (no), then in Step S110, the sequence control unit 22 controls the pattern generation unit 24 to generate the second cycle by means of the signal pattern corresponding to the at least one remaining step and a signal pattern corresponding to at least one step of the second instruction. For example, in the example shown in FIG. 3A, the sequence control unit 22 controls the pattern generation unit 24 to generate Cycle 3 by means of a signal pattern corresponding to the remaining step (A-9) that has not been used for the generation of Cycle 2 and signal patterns corresponding to the steps (B-1) to (B-3) of Instruction B. In this example, Cycle 2 corresponds to the first cycle, and Cycle 3 corresponds to the second cycle. In addition, Instruction A corresponds to the first instruction, and Instruction B corresponds to the second instruction.

In Step S112, the sequence control unit 22 updates, as the at least one remaining step, steps of the first instruction and/or the second instruction that were not used for generation of the second cycle. For example, in the example shown in FIG. 3A, when Cycle 1 corresponds to the first cycle and Cycle 2 corresponds to the second cycle, the sequence control unit 22 updates, as the at least one remaining step, the step (A-9) of Instruction A, which is the first instruction, that was not used for the generation of Cycle 2. In addition, in the example shown in FIG. 3A, when Cycle 2 corresponds to the first cycle and Cycle 3 corresponds to the second cycle, the sequence control unit 22 updates, as the at least one remaining step, the steps (B-4) to (B-9) of Instruction B, which is the second instruction, that were not used for generation of Cycle 3.

In Step S114, the sequence control unit 22 determines whether the generation of the protocol pattern PAT has ended. If it is determined that the generation of the protocol pattern PAT has ended (yes), a generation flow of the protocol pattern PAT ends. If it is determined that the generation of the protocol pattern PAT has not ended (no), the flow may return to Step S102, and the flow described above may be repeated.

In accordance with the flow as described above, the pattern generation unit 24 generates the protocol pattern PAT such that at least one cycle includes signal patterns corresponding to at least one respective step of the plurality of instructions. This allows efficient processing of an instruction having a number of steps greater than the specified number of at least one signal pattern.

It should be noted that, with repetition of the flow, instructions corresponding to the first instruction and the second instruction as well as cycles corresponding to the first cycle and the second cycle may be changed as appropriate. It has been described above that there are cases where Cycle 1 corresponds to the first cycle and Cycle 2 corresponds to the second cycle and where Cycle 2 corresponds to the first cycle and Cycle 3 corresponds to the second cycle. Similarly, those skilled in the art could understand that there may be cases where Cycle 3 corresponds to the first cycle and Cycle 4 corresponds to the second cycle and where Cycle 4 corresponds to the first cycle and a subsequent cycle corresponds to the second cycle as well as where Instruction B corresponds to the first instruction and a subsequent instruction corresponds to the second instruction, etc.

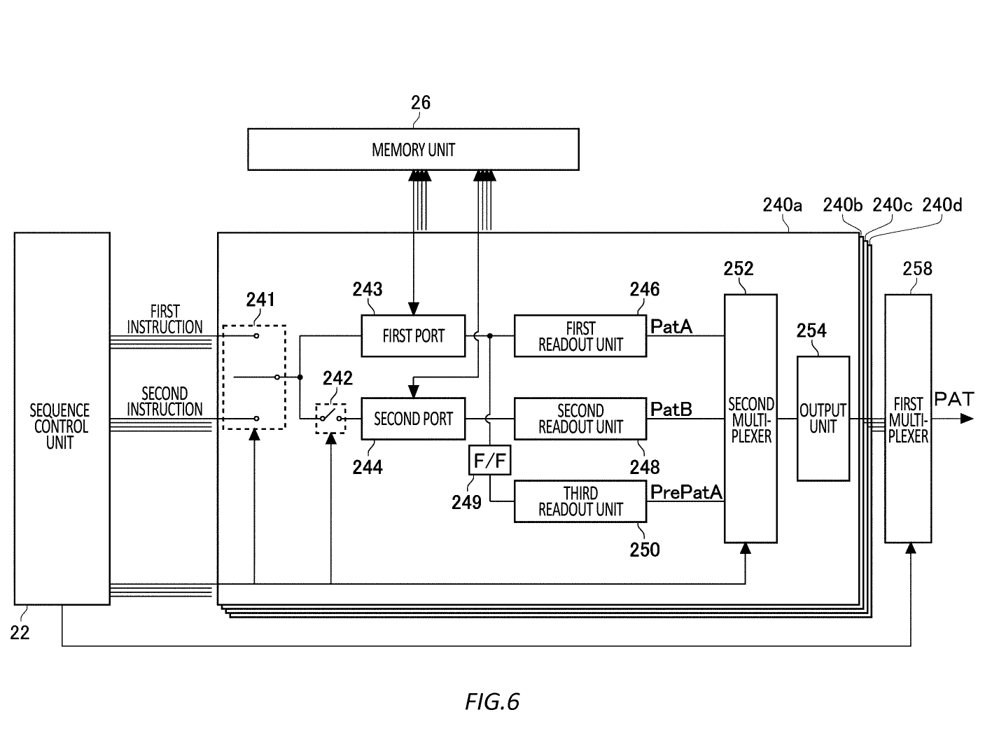

FIG. 6 shows one example of a configuration of the pattern generator 240 together with the sequence control unit 22, the memory unit 26, and the first multiplexer 258. In the present figure, a configuration of a pattern generator 240a of the plurality of pattern generators 240 is shown as a representative, but other pattern generators 240b to 240d may have a similar configuration. The pattern generator 240 may include a first switch unit 241, a second switch unit 242, a first port 243, a second port 244, a first readout unit 246, a second readout unit 248, a third readout unit 250, a flip-flop 249, a second multiplexer 252, and an output unit 254.

The first switch unit 241 may switch a pattern generation signal inputted from the sequence control unit 22. The sequence control unit 22 in the present example inputs, to the pattern generator 240, a pattern generation signal for generating signal patterns corresponding to respective steps of a first instruction and a pattern generation signal for generating signal patterns corresponding to respective steps of a second instruction. The sequence control unit 22 may select which pattern generation signal is to be inputted, by controlling and switching the first switch unit 241. The sequence control unit 22 may control the first switch unit 241 based on at least one remaining step.

The second switch unit 242 may switch whether or not the pattern generation signal inputted from the sequence control unit 22 is to be inputted to the second port 244. That is, the second switch unit 242 may switch whether the pattern generation signal inputted from the sequence control unit 22 is to be inputted to both the first port 243 and the second port 244, or to only the first port 243. The sequence control unit 22 may select the port to which the pattern generation signal is to be inputted, by controlling and switching the second switch unit 242. The sequence control unit 22 may control the second switch unit 242 based on the at least one remaining step.

The first port 243 and the second port 244 access the memory unit 26. The first port 243 and the second port 244 may access the memory unit 26 based on the pattern generation signal inputted from the sequence control unit 22. For example, when the pattern generation signal for generating the signal patterns corresponding to the respective steps of the first instruction is inputted from the sequence control unit 22, the first port 243 and/or second port 244 access an address of the memory unit 26 which stores the signal patterns corresponding to the respective steps of the first instruction. In addition, when the pattern generation signal for generating the signal patterns corresponding to the respective steps of the second instruction is inputted from the sequence control unit 22, the first port 243 and/or second port 244 access an address of the memory unit 26 which stores the signal patterns corresponding to the respective steps of the second instruction.

When a number of at least one remaining step of the first instruction is greater than or equal to a specified number of at least one signal pattern, the first readout unit 246 may read out, from the memory unit 26 via the first port 243, the signal patterns corresponding to the respective steps of the first instruction. When the number of at least one remaining step of the first instruction is smaller than the specified number of at least one signal pattern, the first readout unit 246 may read out, from the memory unit 26 via the first port 243, the signal patterns corresponding to the respective steps of the second instruction. The first readout unit 246 may input a read out a signal pattern PatA to the second multiplexer 252. The sequence control unit 22 may control reading out of the signal patterns by the first readout unit 246 by controlling the first switch unit 241.

When the number of at least one remaining step of the first instruction is greater than or equal to the specified number of at least one signal pattern, the sequence control unit 22 controls the first switch unit 241 to connect to a terminal for inputting the pattern generation signal for generating the signal patterns corresponding to the respective steps of the first instruction. As a result, the first port 243 accesses the address of the memory unit 26 which stores the signal patterns corresponding to the respective steps of the first instruction. Then, the first readout unit 246 reads out, from the memory unit 26 via the first port 243, the signal patterns corresponding to the respective steps of the first instruction.

When the number of at least one remaining step of the first instruction is smaller than the specified number of at least one signal pattern, the sequence control unit 22 controls the first switch unit 241 to connect to a terminal for inputting the pattern generation signal for generating the signal patterns corresponding to the respective steps of the second instruction. As a result, the first port 243 accesses the address of the memory unit 26 which stores the signal patterns corresponding to the respective steps of the second instruction. Then, the first readout unit 246 reads out, from the memory unit 26 via the first port 243, the signal patterns corresponding to the respective steps of the second instruction.

When the number of at least one remaining step of the first instruction is greater than or equal to the specified number of at least one signal pattern, the second readout unit 248 may read out, from the memory unit 26 via the second port 244, signal patterns identical to the signal patterns read out by the first readout unit 246. When the number of at least one remaining step of the first instruction is smaller than the specified number of at least one signal pattern, the second readout unit 248 may read out, from the memory unit 26 via the second port 244, a signal pattern corresponding to the at least one remaining step of the first instruction. The second readout unit 248 may input a read out a signal pattern PatB to the second multiplexer 252. The sequence control unit 22 may control reading out of the signal patterns by the second readout unit 248 by controlling the second switch unit 242.

When the number of at least one remaining step of the first instruction is greater than or equal to the specified number of at least one signal pattern, the sequence control unit 22 controls the second switch unit 242 to be in a connected state. As a result, the pattern generation signal for generating the signal patterns corresponding to the respective steps of the first instruction is inputted to the second port 244, and the second port 244 accesses the address of the memory unit 26 which stores the signal patterns corresponding to the respective steps of the first instruction. Then, the second readout unit 248 reads out, from the memory unit 26 via the second port 244, the signal patterns corresponding to the respective steps of the first instruction, the signal patterns being identical to the signal patterns read out by the first readout unit 246.

When the number of at least one remaining step of the first instruction is smaller than the specified number of at least one signal pattern, the sequence control unit 22 controls the second switch unit 242 to be in a disconnected state. As a result, the pattern generation signal for generating the signal patterns corresponding to the respective steps of the second instruction is not inputted to the second port 244, and the second port 244 maintains access to the address of the memory unit 26 which stores the signal patterns corresponding to the respective steps of the first instruction. Then, the second readout unit 248 reads out, from the memory unit 26 via the second port 244, the signal pattern corresponding to the at least one remaining step of the first instruction.

The third readout unit 250 may read out, from the memory unit 26 via the first port 243, signal patterns identical to signal patterns read out by the first readout unit 246 in an immediately preceding cycle. The third readout unit 250 may read out the signal patterns from the memory unit 26 via the first port 243 and the flip-flop 249. That is, the flip-flop 249 delays, by one cycle, the signal patterns read out by the first readout unit 246, whereby the third readout unit 250 may read out the signal patterns identical to the signal patterns read out by the first readout unit 246 in the immediately preceding cycle. The third readout unit 250 may input a read out a signal pattern PrePatA to the second multiplexer 252.

Arrangement and control of the ports and the switch units for realizing operations of the first readout unit 246, the second readout unit 248, and the third readout unit 250 have been described above, but the present disclosure is not limited thereto. As one example, the signal patterns to be read out by the respective readout units may be controlled by setting the first port 243 to access the address of the memory unit 26 which stores the signal patterns corresponding to the respective steps of the first instruction and the second port 244 to access the address of the memory unit 26 which stores the signal patterns corresponding to the respective steps of the second instruction, and by providing and controlling the switch units between the respective ports and the respective readout units.

The second multiplexer 252 is provided between the first port 243 and the second port 244, and the output unit 254. The second multiplexer 252 may select a signal pattern to be outputted from each of the plurality of pattern generators 240. The second multiplexer 252 may select, from among the signal patterns read out by the first readout unit 246, the second readout unit 248, and the third readout unit 250, the signal pattern to be outputted from each of the plurality of pattern generators 240. The sequence control unit 22 may control selection of the signal pattern by the second multiplexer 252 based on the at least one remaining step. The selection of the signal pattern by the second multiplexer 252 will be described later in detail.

The output unit 254 outputs the signal patterns stored in the memory unit 26. The output unit 254 may output, to the first multiplexer 258, the signal pattern selected by the second multiplexer 252.

The first multiplexer 258 may output, as one continuous signal pattern, a composition of signal patterns respectively outputted from the plurality of pattern generators 240.

The second multiplexer 252 has been described above as performing a 3-to-1 operation to select one signal pattern from among the three signal patterns PatA, PatB, and PrePatA, and the first multiplexer 258 has been described as performing a 4-to-1 operation to combine the signal patterns from the four pattern generators 240 into one signal pattern, but the present disclosure is not limited thereto. As one example, the first multiplexer 258 and the second multiplexers 252 of the respective pattern generators 240 may be configured as one multiplexer as a whole, and said multiplexer may perform a 12-to-1 operation to output, as one continuous signal pattern, a composition of 12 signal patterns (PatA, PatB, PrePatA × 4).

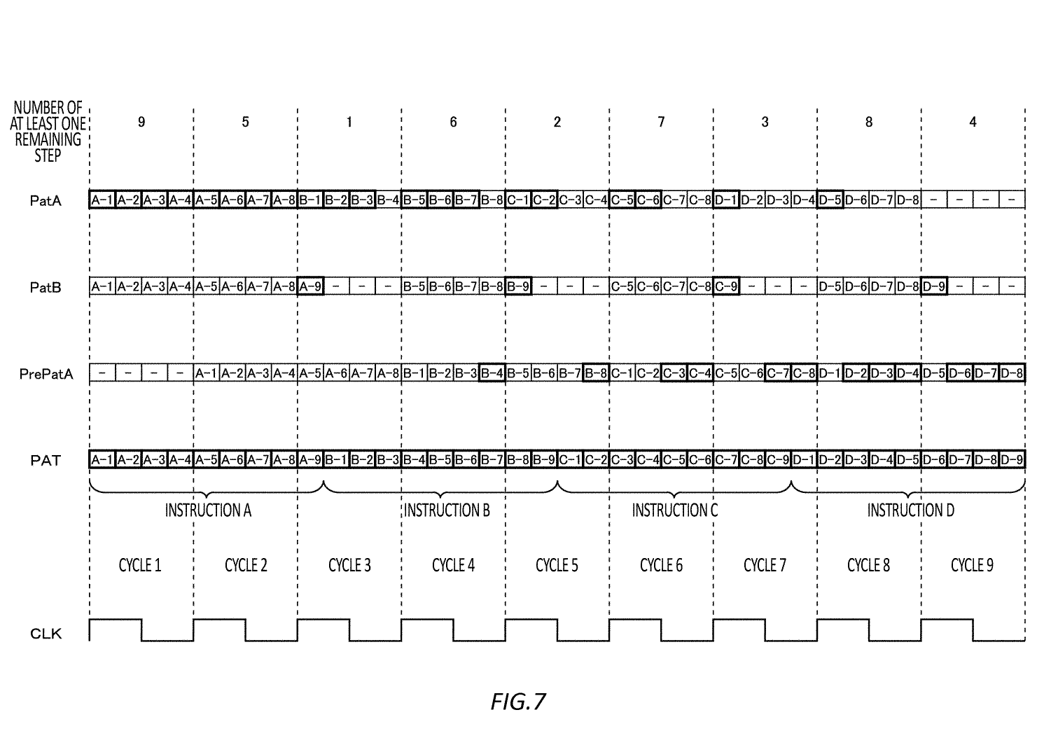

FIG. 7 shows a modified example of generation of a protocol pattern PAT. In the present example, numbers of at least one remaining step, a signal pattern PatA read out by the first readout unit 246, a signal pattern PatB read out by the second readout unit 248, and the protocol pattern PAT outputted from the first multiplexer 258 are shown together with cycles synchronized with a clock signal CLK produced by the timing producing unit 28. The present example shows a case where the protocol pattern PAT corresponding to Instruction A, Instruction B, Instruction C, and Instruction D, each having nine steps, is generated.

The pattern generation unit 24 generates Cycle 1 including signal patterns corresponding to the steps (A-1) to (A-4) of the plurality of steps (A-1) to (A-9) included in Instruction A (S100 in FIG. 5).

At the beginning of generation of Cycle 1, since all steps of Instruction A are remaining steps and a number of those steps is nine, this corresponds to a case where a number of at least one remaining step of a first instruction (Instruction A in this case) is greater than or equal to a specified number of at least one signal pattern (four in this case). Therefore, the first readout unit 246 reads out, from the memory unit 26, the signal patterns corresponding to the steps (A-1) to (A-4) of Instruction A (PatA). The second readout unit 248 reads out the signal patterns corresponding to the steps (A-1) to (A-4) of Instruction A, the signal patterns being identical to the signal patterns read out by the first readout unit 246 (PatB). In Cycle 1, since there is no immediately preceding cycle, the third readout unit 250 does not read out any signal pattern (PrePatA). These operations may be the same in each of the plurality of pattern generators 240.

The second multiplexer 252 selects a signal pattern to be outputted from each of the plurality of pattern generators 240. The sequence control unit 22 may control selection of the signal pattern by the second multiplexer 252 of each of the plurality of pattern generators 240 such that a desired protocol pattern PAT can be generated. For example, in response to a control signal from the sequence control unit 22, the second multiplexer 252 of the pattern generator 240a selects, from the signal pattern PatA, a signal pattern corresponding to the step (A-1); the second multiplexer 252 of the pattern generator 240b selects, from the signal pattern PatA, a signal pattern corresponding to the step (A-2); the second multiplexer 252 of the pattern generator 240c selects, from the signal pattern PatA, a signal pattern corresponding to the step (A-3); and the second multiplexer 252 of the pattern generator 240d selects, from the signal pattern PatA, a signal pattern corresponding to the step (A-4).

In the present example, the selected signal patterns are indicated by bold frames. In the present example, all signal patterns are selected from the signal pattern PatA read out by the first readout unit 246, but the present disclosure is not limited thereto. That is, in Cycle 1, since the second readout unit 248 has read out identical signal patterns, the second multiplexer 252 may perform selection from the signal pattern PatB read out by the second readout unit 248.

The first multiplexer 258 outputs, as one continuous signal pattern, a composition of signal patterns respectively outputted from the plurality of pattern generators 240. The first multiplexer 258 may combine the signal patterns respectively outputted from the plurality of pattern generators 240 in a predetermined order. The first multiplexer 258 in the present example outputs, as the protocol pattern PAT, the signal patterns corresponding to the steps (A-1) to (A-4), by combining signal patterns outputted from the pattern generator 240a, the pattern generator 240b, the pattern generator 240c, and the pattern generator 240d in this order.

The sequence control unit 22 determines presence or absence of at least one remaining step, of the plurality of steps included in Instruction A, that has not been used for the generation of Cycle 1 (Step S102 in FIG. 5). In the present example, the sequence control unit 22 determines that there are remaining steps, (A-5) to (A-9).

The sequence control unit 22 determines whether a number of the at least one remaining step is greater than or equal to the specified number of at least one signal pattern (Step S106 in FIG. 5). In the present example, the number of at least one remaining step is five, which is determined to be greater than or equal to the specified number of at least one signal pattern, four.

The sequence control unit 22 controls the pattern generation unit 24 to generate Cycle 2 by means of signal patterns corresponding to the remaining steps (A-5) to (A-8) (Step S108 in FIG. 5).

At the beginning of generation of Cycle 2, since the number of at least one remaining step is five, this corresponds to a case where the number of at least one remaining step of the first instruction (Instruction A in this case) is greater than or equal to the specified number of at least one signal pattern (four in this case). Therefore, since operations of the readout units and the multiplexer are similar to those in Cycle 1, a repeated description will be omitted. In Cycle 2, since there is an immediately preceding cycle, the third readout unit 250 has read out, from the memory unit 26, signal patterns (A-1) to (A-4) identical to the signal patterns read out by the first readout unit 246 in Cycle 1 (PrePatA).

The sequence control unit 22 updates, as the at least one remaining step, the step (A-9) of Instruction A that was not used for the generation of Cycle 2 (Step S112 in FIG. 5). The sequence control unit 22 determines whether the generation of the protocol pattern PAT has ended (Step S114 in FIG. 5). Since the generation of the protocol pattern PAT has not ended, the flow returns to Step S102 in FIG. 5, and the operation continues.

The sequence control unit 22 determines presence or absence of at least one remaining step (Step S102 in FIG. 5). Here, the sequence control unit 22 determines that there is a remaining step (A-9).

The sequence control unit 22 determines whether the number of the at least one remaining step is greater than or equal to the specified number of at least one signal pattern (Step S106 in FIG. 5). In the present example, the number of at least one remaining step is one, which is determined to be smaller than the specified number of at least one signal pattern, four.

The sequence control unit 22 controls the pattern generation unit 24 to generate Cycle 3 by means of a signal pattern corresponding to the remaining step (A-9) and a signal pattern corresponding to at least one step of Instruction B (Step S110 in FIG. 5).

At the beginning of generation of Cycle 3, since the number of at least one remaining step is one, this corresponds to a case where the number of at least one remaining step is smaller than the specified number of at least one signal pattern (four in this case). Therefore, the first readout unit 246 reads out, from the memory unit 26, signal patterns corresponding to the steps (B-1) to (B-4) of Instruction B (PatA). The second readout unit 248 reads out, from the memory unit 26, the signal pattern corresponding to the remaining step (A-9) of Instruction A (PatB). The third readout unit 250 reads out, from the memory unit 26, signal patterns (A-5) to (A-8) identical to the signal patterns read out by the first readout unit 246 in Cycle 2 (PrePatA).

The second multiplexer 252 of the pattern generator 240a may select, from the signal pattern PatB, a signal pattern corresponding to the step (A-9); the second multiplexer 252 of the pattern generator 240b may select, from the signal pattern PatA, a signal pattern corresponding to the step (B-1); the second multiplexer 252 of the pattern generator 240c may select, from the signal pattern PatA, a signal pattern corresponding to the step (B-2); and the second multiplexer 252 of the pattern generator 240d may select, from the signal pattern PatA, a signal pattern corresponding to the step (B-3). The first multiplexer 258 may output, as the protocol pattern PAT, signal patterns corresponding to the steps (A-9), (B-1) to (B-3), by combining signal patterns outputted from the pattern generator 240a, the pattern generator 240b, the pattern generator 240c, and the pattern generator 240d in this order.

Thus, the first readout unit 246 and the second readout unit 248 read out signal patterns corresponding to respective steps of different instructions with reference to different addresses of the memory unit 26, whereby the pattern generation unit 24 in the present example generates the protocol pattern PAT such that at least one cycle includes signal patterns corresponding to at least one respective step of a plurality of instructions. This allows efficient processing of an instruction having a number of steps greater than the specified number of at least one signal pattern.

The sequence control unit 22 updates, as the at least one remaining step, the steps (B-4) to (B-9) of Instruction B that were not used for the generation of Cycle 3 (Step S112 in FIG. 5). The sequence control unit 22 determines whether the generation of the protocol pattern PAT has ended (Step S114 in FIG. 5). Since the generation of the protocol pattern PAT has not ended, the flow returns to Step S102 in FIG. 5, and the operation continues.

The sequence control unit 22 determines presence or absence of at least one remaining step (Step S102 in FIG. 5). Here, the sequence control unit 22 determines that there are remaining steps, (B-4) to (B-9).

The sequence control unit 22 determines whether the number of the at least one remaining step is greater than or equal to the specified number of at least one signal pattern (Step S106 in FIG. 5). In the present example, the number of at least one remaining step is six, which is determined to be greater than or equal to the specified number of at least one signal pattern, four.

The sequence control unit 22 controls the pattern generation unit 24 to generate Cycle 4 by means of signal patterns corresponding to the remaining steps (B-4) to (B-7) (Step S108 in FIG. 5).

At the beginning of generation of Cycle 4, since the number of at least one remaining step is six, this corresponds to a case where a number of at least one remaining step of the first instruction (Instruction B in this case) is greater than or equal to the specified number of at least one signal pattern (four in this case). The first readout unit 246 reads out, from the memory unit 26, signal patterns corresponding to the steps (B-5) to (B-8) of Instruction B (PatA). The second readout unit 248 reads out the signal patterns corresponding to the steps (B-5) to (B-8) of Instruction B, the signal patterns being identical to the signal patterns read out by the first readout unit 246 (PatB). The third readout unit 250 reads out, from the memory unit 26, signal patterns (B-1) to (B-4) identical to the signal patterns read out by the first readout unit 246 in Cycle 3 (PrePatA).

The second multiplexer 252 of the pattern generator 240a selects, from the signal pattern PatA, a signal pattern corresponding to the step (B-5); the second multiplexer 252 of the pattern generator 240b selects, from the signal pattern PatA, a signal pattern corresponding to the step (B-6); the second multiplexer 252 of the pattern generator 240c selects, from the signal pattern PatA, a signal pattern corresponding to the step (B-7); and the second multiplexer 252 of the pattern generator 240d selects, from a signal pattern PrePatA, a signal pattern corresponding to the step (B-4). The first multiplexer 258 outputs, as the protocol pattern PAT the signal patterns corresponding to the steps (B-4) to (B-7), by combining signal patterns outputted from the pattern generator 240d, the pattern generator 240a, the pattern generator 240b, and the pattern generator 240c in this order.

Thus, the third readout unit 250 reads out, from the memory unit 26, signal patterns identical to the signal patterns read out by the first readout unit 246 in an immediately preceding cycle, whereby the pattern generation unit 24 in the present example can reference a signal pattern that was not used in the immediately preceding cycle, and can eliminate a reference misalignment caused when at least one cycle includes signal patterns corresponding to at least one respective step of a plurality of instructions. As a result, the pattern generation unit 24 generates the protocol pattern PAT such that at least one cycle includes signal patterns corresponding to at least one respective step of a plurality of instructions, thereby allowing the efficient processing of the instruction having the number of steps greater than the specified number of at least one signal pattern.

In addition, since the first multiplexer 258 outputs, as one continuous signal pattern, a composition of signal patterns respectively outputted from the plurality of pattern generators 240, the pattern generation unit 24 in the present example can generate the protocol pattern PAT in which the signal patterns outputted from the plurality of pattern generators 240 are appropriately rearranged, even when the order of patterns outputted from the plurality of pattern generators 240 is different from the order of steps included in the instruction. As a result, the pattern generation unit 24 generates the protocol pattern PAT such that at least one cycle includes signal patterns corresponding to at least one respective step of a plurality of instructions, thereby allowing the efficient processing of the instruction having the number of steps greater than the specified number of at least one signal pattern.

The sequence control unit 22 updates, as the at least one remaining step, the steps (B-8), (B-9) of Instruction B that were not used for the generation of Cycle 4 (Step S112 in FIG. 5). The sequence control unit 22 determines whether the generation of the protocol pattern PAT has ended (Step S114 in FIG. 5). Since the generation of the protocol pattern PAT has not ended, the flow returns to Step S102 in FIG. 5, and the operation continues. By repeating the above operations, the pattern generation unit 24 may generate the protocol pattern PAT having nine cycles, each cycle consisting of a predetermined specified number of at least one signal pattern, four.

Various embodiments of the present invention may be described with reference to flowcharts and block diagrams, whose blocks may represent (1) stages of processes in which operations are executed or (2) sections of apparatuses responsible for executing operations. Specific stages and sections may be implemented by a dedicated circuit, a programmable circuit supplied together with computer-readable instructions stored on computer-readable medium, and/or processors supplied together with computer-readable instructions stored on computer-readable medium. The dedicated circuit may include a digital and/or analog hardware circuit, or may include an integrated circuit (IC) and/or a discrete circuit. The programmable circuit may include a reconfigurable hardware circuit including logical AND, logical OR, logical XOR, logical NAND, logical NOR, and other logical operations, a memory element such as a flip-flop, a register, a field programmable gate array (FPGA) and a programmable logic array (PLA), and the like.

A computer-readable medium may include any tangible device that can store instructions to be executed by an appropriate device, and as a result, the computer-readable medium having instructions stored thereon includes an article of manufacture including instructions which can be executed in order to create means for performing operations specified in the flowcharts or block diagrams. Examples of computer-readable media may include an electronic storage medium, a magnetic storage medium, an optical storage medium, an electromagnetic storage medium, a semiconductor storage medium, and the like. More specific examples of computer-readable media may include a floppy (registered trademark) disk, a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disk (DVD), a BLU-RAY (registered trademark) disk, a memory stick, an integrated circuit card, and the like.

Computer-readable instructions may include assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk (registered trademark), JAVA (registered trademark), C++, etc., and conventional procedural programming languages, such as the "C" programming language or similar programming languages.

Computer-readable instructions may be provided to a processor of a programmable data processing apparatus such as a computer, or to a programmable circuit, locally or via a local area network (LAN), wide area network (WAN) such as the Internet, or the like, to execute the computer-readable instructions in order to create means for performing operations specified in the flowcharts or block diagrams. Here, the computer may be a personal computer (PC), a tablet computer, a smartphone, a workstation, a server computer, a general-purpose computer, a special-purpose computer, or the like, or may be a computer system in which a plurality of computers are connected to each other. Such a computer system in which a plurality of computers are connected to each other is also referred to as a distributed computing system, and constitutes a computer in a broad sense. In a distributed computing system, a plurality of computers execute respective portions of a program, and as necessary, exchange data during execution of the program between the computers, whereby the plurality of computers collectively execute the program.

Examples of processors include computer processors, central processing units (CPU), processing units, microprocessors, digital signal processors, controllers, microcontrollers, and the like. The computer may include one processor or a plurality of processors. In a multiprocessor system including a plurality of processors, the processors execute respective portions of a program, and as necessary, exchange data during execution of the program between the processors, whereby the plurality of processors collectively execute the program. For example, during execution of multitasking, a plurality of processors may execute respective fragmented portions of respective tasks by performing task switching at each time slice. In this case, the portion of one program to be executed by each processor dynamically changes. The portion of a program to be executed by each of a plurality of processors may be statically determined through programming designed with consideration for a multiprocessor.

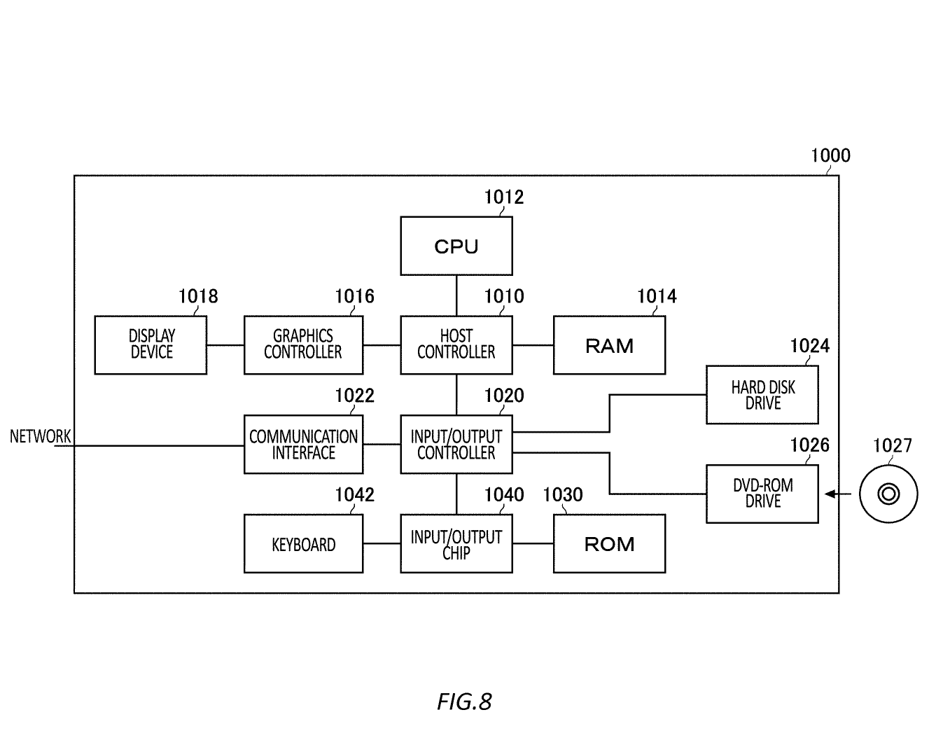

FIG. 8 shows one example of a computer 1000 in which a plurality of aspects of the present invention may be embodied in whole or in part. A program that is installed in the computer 1000 can cause the computer 1000 to function as or perform operations associated with apparatuses according to the embodiments of the present invention or one or more sections of said apparatuses, and/or cause the computer 1000 to perform processes according to the embodiments of the present invention or stages of said processes. Such a program may be executed by the CPU 1012 in order to cause the computer 1000 to perform specific operations associated with some or all of the blocks of flowcharts and block diagrams described herein.

The computer 1000 according to the present embodiment includes a CPU 1012, a RAM 1014, a graphics controller 1016, and a display device 1018, which are mutually connected by a host controller 1010. The computer 1000 also includes an input/output unit such as a communication interface 1022, a hard disk drive 1024, a DVD-ROM drive 1026, and an IC card drive, which are connected to the host controller 1010 via an input/output controller 1020. The computer also includes legacy input/output units such as a ROM 1030 and a keyboard 1042, which are connected to the input/output controller 1020 via an input/output chip 1040.

The CPU 1012 operates in accordance with programs stored in the ROM 1030 and the RAM 1014, thereby controlling each unit. The graphics controller 1016 acquires image data generated by the CPU 1012 on a frame buffer or the like provided in the RAM 1014 or in itself, and causes the image data to be displayed on the display device 1018.

The communication interface 1022 communicates with other electronic devices via a network. The hard disk drive 1024 stores programs and data used by the CPU 1012 within the computer 1000. The DVD-ROM drive 1026 reads the programs or the data from the DVD-ROM 1027, and provides the hard disk drive 1024 with the programs or the data via the RAM 1014. The IC card drive reads programs and data from an IC card, and/or writes programs and data into the IC card.

The ROM 1030 stores therein a boot program or the like executed by the computer 1000 at the time of activation, and/or a program depending on the hardware of the computer 1000. The input/output chip 1040 may also connect various input/output units via a parallel port, a serial port, a keyboard port, a mouse port, or the like to the input/output controller 1020.

A program is provided by computer-readable medium such as the DVD-ROM 1027 or the IC card. The program is read from the computer-readable medium, installed into the hard disk drive 1024, RAM 1014, or ROM 1030, which are also examples of computer-readable media, and executed by the CPU 1012. The information processing written in these programs is read into the computer 1000, resulting in cooperation between a program and the above various types of hardware resources. An apparatus or method may be configured by realizing the operation or processing of information in accordance with the usage of the computer 1000.

For example, when communication is executed between the computer 1000 and an external device, the CPU 1012 may execute a communication program loaded onto the RAM 1014, and instruct the communication interface 1022 to process the communication based on the processing written in the communication program. Under control of the CPU 1012, the communication interface 1022 reads transmission data stored in a transmission buffer processing region provided in a recording medium such as the RAM 1014, the hard disk drive 1024, the DVD-ROM 1027, or the IC card, and transmits the read out transmission data to the network, or writes reception data received from the network to a reception buffer processing region or the like provided on the recording medium.

In addition, the CPU 1012 may cause all or a necessary portion of a file or a database to be read into the RAM 1014, the file or the database having been stored in an external recording medium such as the hard disk drive 1024, the DVD-ROM drive 1026 (DVD-ROM 1027), the IC card, etc. and perform various types of processes on data on the RAM 1014. Next, the CPU 1012 may write back the processed data to the external recording medium.

Various types of information, such as various types of programs, data, tables, and databases, may be stored in the recording medium to undergo information processing. The CPU 1012 may perform various types of processing on the data read from the RAM 1014, which includes various types of operations, information processing, conditional judgement, conditional branching, unconditional branching, search/replacement of information, etc., as described throughout the present disclosure and specified by an instruction sequence of programs, and writes the result back to the RAM 1014. In addition, the CPU 1012 may search for information in a file, a database, etc., in the recording medium. For example, when a plurality of entries, each having an attribute value of a first attribute associated with an attribute value of a second attribute, are stored in the recording medium, the CPU 1012 may search for an entry matching the condition whose attribute value of the first attribute is specified, from among said plurality of entries, and read the attribute value of the second attribute stored in said entry, thereby acquiring the attribute value of the second attribute associated with the first attribute satisfying the predetermined condition.

The program or software modules described above may be stored in the computer-readable medium on or near the computer 1000. In addition, a recording medium such as a hard disk or a RAM provided in a server system connected to a dedicated communication network or the Internet can be used as the computer-readable medium, thereby providing the program to the computer 1000 via the network.

While the present invention has been described above using the embodiments, the technical scope of the present invention is not limited to the scope described in the above embodiments. It is apparent to those skilled in the art that various modifications or improvements can be made to the above embodiments. It is apparent from the description of the claims that embodiments with such modifications or improvements may also be included in the technical scope of the present invention.

It should be noted that the order of execution of respective processes such as the operations, procedures, steps, and stages in the apparatus, system, program, and method shown in the claims, the specification, and the drawings may be realized in any order, unless otherwise specified as "before”, “preceding”, or the like, and unless the output of a previous process is used in a later process. Even when terms such as “first” and “next” are used for convenience in describing the operation flows in the claims, specification, and drawings, this does not mean that the operations must be performed in this order.

### EXPLANATION OF REFERENCES

10: device under test, 20: ALPG, 22: sequence control unit, 24: pattern generation unit, 26: memory unit, 28: timing producing unit, 30: input unit, 40: acquisition unit, 50: determination unit, 100: test apparatus, 240: pattern generator, 241: first switch unit, 242: second switch unit, 243: first port, 244: second port, 246: first readout unit, 248: second readout unit, 249: flip-flop, 250: third readout unit, 252: second multiplexer, 254: output unit, 258: first multiplexer, 1000: computer, 1010: host controller, 1012: CPU, 1014: RAM, 1016: graphics controller, 1018: display device, 1020: input/output controller, 1022: communication interface, 1024: hard disk drive, 1026: DVD-ROM drive, 1027: DVD-ROM, 1030: ROM, 1040: input/output chip, 1042: keyboard.

What is claimed is:

1. A test apparatus comprising:
a pattern generation unit which generates a protocol pattern for testing a device under test, the protocol pattern having a plurality of cycles, each cycle consisting of a predetermined specified number of at least one signal pattern; and
a sequence control unit which controls the pattern generation unit in accordance with a first instruction having a plurality of steps and a second instruction having a plurality of steps,
wherein the pattern generation unit generates the protocol pattern such that at least one cycle of the plurality of cycles includes a signal pattern corresponding to at least one step included in the first instruction and a signal pattern corresponding to at least one step included in the second instruction.

2. The test apparatus according to claim 1, wherein
a number of the plurality of steps included in the first instruction is greater than the specified number of at least one signal pattern.

3. The test apparatus according to claim 1, wherein
the pattern generation unit generates a first cycle including a signal pattern corresponding to at least one step of the plurality of steps included in the first instruction, and
the sequence control unit:
determines presence or absence of at least one remaining step, of the plurality of steps included in the first instruction, that has not been used for generation of the first cycle;
if the at least one remaining step is absent, controls the pattern generation unit to generate a second cycle, which is a cycle following the first cycle, by means of a signal pattern corresponding to at least one step of the second instruction;
if the at least one remaining step is present and a number of the at least one remaining step is greater than or equal to the specified number of at least one signal pattern, controls the pattern generation unit to generate the second cycle by means of a signal pattern corresponding to the at least one remaining step; and
if the at least one remaining step is present and the number of the at least one remaining step is smaller than the specified number of at least one signal pattern, controls the pattern generation unit to generate the second cycle by means of the signal pattern corresponding to the at least one remaining step and a signal pattern corresponding to at least one step of the second instruction.

4. The test apparatus according to claim 3, wherein
the sequence control unit updates, as the at least one remaining step, steps of the first instruction and/or the second instruction that were not used for generation of the second cycle.

5. The test apparatus according to claim 2, wherein
the pattern generation unit generates a first cycle including a signal pattern corresponding to at least one step of the plurality of steps included in the first instruction, and
the sequence control unit:
determines presence or absence of at least one remaining step, of the plurality of steps included in the first instruction, that has not been used for generation of the first cycle;
if the at least one remaining step is absent, controls the pattern generation unit to generate a second cycle, which is a cycle following the first cycle, by means of a signal pattern corresponding to at least one step of the second instruction;
if the at least one remaining step is present and a number of the at least one remaining step is greater than the specified number of at least one signal pattern, controls the pattern generation unit to generate the second cycle by means of a signal pattern corresponding to the at least one remaining step; and
if the at least one remaining step is present and the number of the at least one remaining step is smaller than or equal to the specified number of at least one signal pattern, controls the pattern generation unit to generate the second cycle by means of the signal pattern corresponding to the at least one remaining step and a signal pattern corresponding to at least one step of the second instruction.

6. The test apparatus according to claim 5, wherein
the sequence control unit updates, as the at least one remaining step, steps of the first instruction and/or the second instruction that were not used for generation of the second cycle.

7. The test apparatus according to claim 1, wherein
the pattern generation unit has a plurality of pattern generators, each generating a signal pattern corresponding to at least one step of the first instruction or the second instruction.

8. The test apparatus according to claim 7, wherein
the pattern generation unit has a first multiplexer which outputs, as one continuous signal pattern, a composition of signal patterns respectively outputted from the plurality of pattern generators.

9. The test apparatus according to claim 7, comprising
a memory unit which stores signal patterns corresponding to respective steps of the first instruction and the second instruction,
wherein each of the plurality of pattern generators includes:
a port for accessing the memory unit;
an output unit for outputting a signal pattern stored in the memory unit; and
a second multiplexer which is provided between the port and the output unit and selects the signal pattern to be outputted from each of the plurality of pattern generators.

10. The test apparatus according to claim 9, wherein
each of the plurality of pattern generators includes a first readout unit which, when a number of at least one remaining step of the first instruction is greater than or equal to the specified number of at least one signal pattern, reads out, from the memory unit via the port, the signal patterns corresponding to the respective steps of the first instruction, and which, when the number of at least one remaining step of the first instruction is smaller than the specified number of at least one signal pattern, reads out, from the memory unit via the port, the signal patterns corresponding to the respective steps of the second instruction.

11. The test apparatus according to claim 10, wherein
each of the plurality of pattern generators includes a second readout unit which, when the number of at least one remaining step of the first instruction is greater than or equal to the specified number of at least one signal pattern, reads out, from the memory unit via the port, signal patterns identical to the signal patterns read out by the first readout unit, and which, when the number of at least one remaining step of the first instruction is smaller than the specified number of at least one signal pattern, reads out, from the memory unit via the port, a signal pattern corresponding to the at least one remaining step of the first instruction.

12. The test apparatus according to claim 11, wherein
each of the plurality of pattern generators includes a third readout unit which reads out, from the memory unit via the port, signal patterns identical to signal patterns read out by the first readout unit in an immediately preceding cycle.

13. The test apparatus according to claim 12, wherein
the second multiplexer selects, from among the signal patterns read out by the first readout unit, the second readout unit, and the third readout unit, the signal pattern to be outputted from each of the plurality of pattern generators.

14. The test apparatus according to claim 2, wherein
the pattern generation unit has a plurality of pattern generators, each generating a signal pattern corresponding to at least one step of the first instruction or the second instruction.

15. The test apparatus according to claim 7, wherein
the specified number of at least one signal pattern is equal to a number of the plurality of pattern generators.

16. The test apparatus according to claim 8, wherein
the specified number of at least one signal pattern is equal to a number of the plurality of pattern generators.

17. The test apparatus according to claim 1, wherein
the specified number of at least one signal pattern is a power of two.

18. The test apparatus according to claim 2, wherein
the specified number of at least one signal pattern is a power of two.

19. A test method comprising:
generating, by a computer, a protocol pattern for testing a device under test, the protocol pattern having a plurality of cycles, each cycle consisting of a predetermined specified number of at least one signal pattern; and
controlling, by a computer, generation of the protocol pattern, in accordance with a first instruction having a plurality of steps and a second instruction having a plurality of steps,
wherein the generating the protocol pattern includes generating the protocol pattern such that at least one cycle of the plurality of cycles includes a signal pattern corresponding to at least one step included in the first instruction and a signal pattern corresponding to at least one step included in the second instruction.

20. A non-transitory computer-readable medium having recorded thereon a program which, when executed by a computer, causes the computer to function as:
a pattern generation unit which generates a protocol pattern for testing a device under test, the protocol pattern having a plurality of cycles, each cycle consisting of a predetermined specified number of at least one signal pattern; and
a sequence control unit which controls the pattern generation unit in accordance with a first instruction having a plurality of steps and a second instruction having a plurality of steps,
wherein the pattern generation unit generates the protocol pattern such that at least one cycle of the plurality of cycles includes a signal pattern corresponding to at least one step included in the first instruction and a signal pattern corresponding to at least one step included in the second instruction.
